(19) United States
(12) Patent Application Publication
(10) Pub. No.: US 2012/0009787 A1
(43) Pub. Date: Jan. 12, 2012

(54) METHOD FOR FORMING MASKING LAYER BY USING ION IMPLANTATION AND SEMICONDUCTOR DEVICE FABRICATED BY USING THE SAME

(76) Inventor: Won-Kyu KIM, Gyeonggi-do (KR)

(21) Appl. No.: 12/948,338

(22) Filed: Nov. 17, 2010

(30) Foreign Application Priority Data
Jul. 7, 2010 (KR) 10-2010-0065362

(51) Int. Cl. H01L 21/60; H01L 21/02

(52) U.S. Cl. 438/674; 438/691; 438/699; 257/E21.002; 257/E21.506

(57) ABSTRACT

A method for forming a masking layer of a semiconductor device includes forming a plurality of pillar structures separated by a trench, forming a gap-fill material partially filling the trench and exposing an upper sidewall of each pillar structure, forming a masking layer that covers the pillar structures and the gap-fill material, performing an ion implantation to the masking layer to form an implanted portion covering upper portion of the gap-fill material and one side of the upper sidewalls of each pillar structure and a non-implanted portion covering the other side of the upper sidewalls of each pillar structure, forming a sacrificial layer over the masking layer, exposing the non-implanted portion of the masking layer, and selectively removing the exposed non-implanted portion.

### CROSS-REFERENCE TO RELATED APPLICATIONS

The present application claims priority of Korean Patent Application No. 10-2010-0065362, filed on Jul. 7, 2010, which is incorporated herein by reference in its entirety.

### BACKGROUND OF THE INVENTION

Exemplary embodiments of the present invention relate to a method for fabricating a semiconductor device, and more particularly, to a method for forming a masking layer by using ion implantation and a method for fabricating a semiconductor device by using the same.

A cell with a vertical transistor structure has a three-dimensional structure, including a buried bit line (BBL) and a vertical gate (VG). The VG is formed at a sidewall of a pillar, and a source and a drain are formed in the pillar. A channel in the vertical direction is formed between the source and the drain by applying a voltage to the VG. Adjacent pillars are separated from each other by a trench, and a BBL is formed in the trench. The BBL is electrically coupled to one sidewall of each pillar. In order to drive one cell per one BBL, a one-side-contact (OSC) process is necessary. According to the OSC process, one of adjacent pillars is insulated from a BLL and a bit line contact (BLC) is formed in the other pillar to electrically couple the BLL.

That is, as a result of the OSC process, one sidewall of each pillar is partially exposed.

However, as an aspect ratio of a pillar increases, the OSC process becomes increasingly complicated.

When the OSC process is performed using a general mask process, the ability to accurately overlay the general mask onto a lower structure is desired.

### SUMMARY OF THE INVENTION

Exemplary embodiments of the present invention are directed to a method for forming a masking layer of a semiconductor device, which is capable of ensuring a relatively wide process window.

Exemplary embodiments of the present invention are also directed to a method for fabricating a semiconductor device, which is capable of forming a bit line contact for opening one sidewall of a pillar while forming a cell having a vertical transistor structure.

In accordance with an exemplary embodiment of the present invention, a method for forming a masking layer of a semiconductor device includes forming a plurality of pillar structures separated by a trench, forming a gap-fill material partially filling the trench and exposing an upper sidewall of each pillar structure, forming a masking layer that covers the pillar structures and the gap-fill material, performing an ion implantation to the masking layer to form an implanted portion covering upper portion of the gap-fill material and one side of the upper sidewalls of each pillar structure and a non-implanted portion covering the other side of the upper sidewalls of each pillar structure, forming a sacrificial layer over the masking layer, exposing the non-implanted portion of the masking layer, and selectively removing the exposed non-implanted portion.

In accordance with another exemplary embodiment of the present invention, a method for fabricating a semiconductor device includes forming a plurality of pillar structures separated by a trench, forming a gap-fill material partially filling the trench and exposing an upper sidewall of each pillar structure, forming a masking layer that covers the pillar structures and the gap-fill material, performing an ion implantation to the masking layer to form an implanted portion covering upper portion of the gap-fill material and one side of the upper sidewalls of each pillar structure and a non-implanted portion covering the other side of the upper sidewalls of each pillar structure, exposing the non-implanted portion of the masking layer, selectively removing the exposed non-implanted portion, and forming a bit line contact for exposing a part of one sidewall of each pillar structure by partially removing a gap-fill material under the removed non-implanted portion.

In accordance with yet another exemplary embodiment of the present invention, method for fabricating a mask of a semiconductor device, includes forming a masking layer including a bottom surface and a sidewall; forming a sacrificial layer covering the masking layer; and performing an ion implantation to dope the bottom surface and an upper portion of the sidewall and undope a lower portion of the sidewall.

### BRIEF DESCRIPTION OF THE DRAWINGS

FIGS. 1A to 1H are cross-sectional views showing a method for fabricating a semiconductor device in accordance with an exemplary embodiment of the present invention.

FIG. 2 is a diagram showing the resultant structure after a buried bit line is formed.

FIGS. 3A to 3F are cross-sectional views showing an example of how a pillar and a gap-fill material shown in FIG. 1A may be formed.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

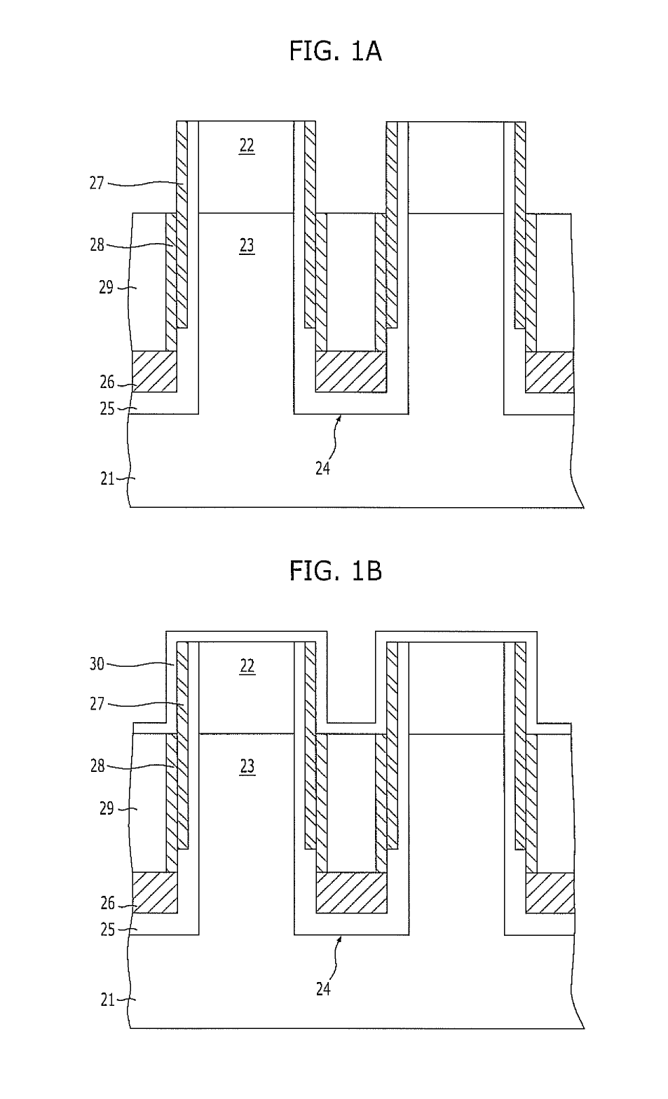

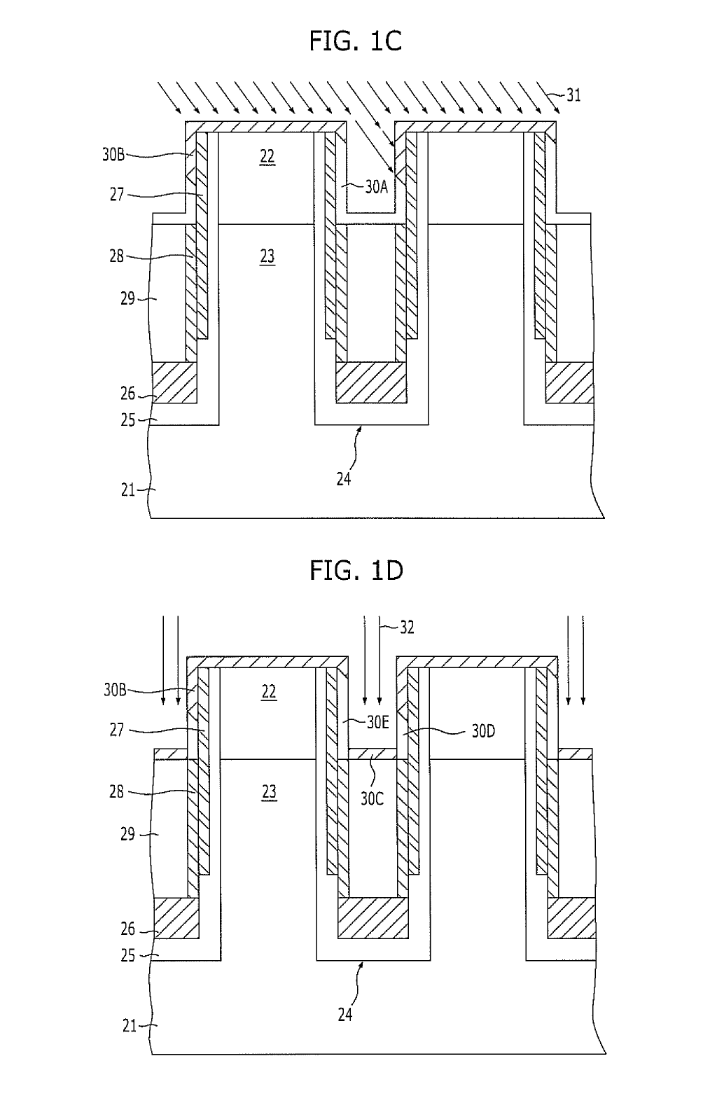

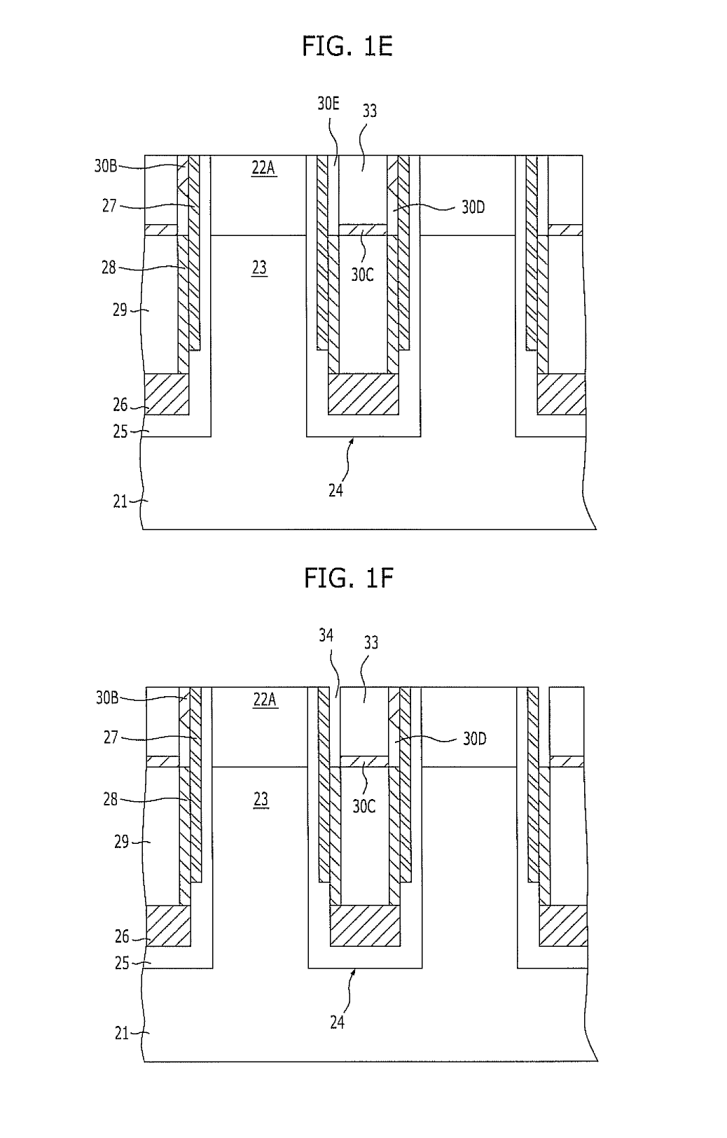

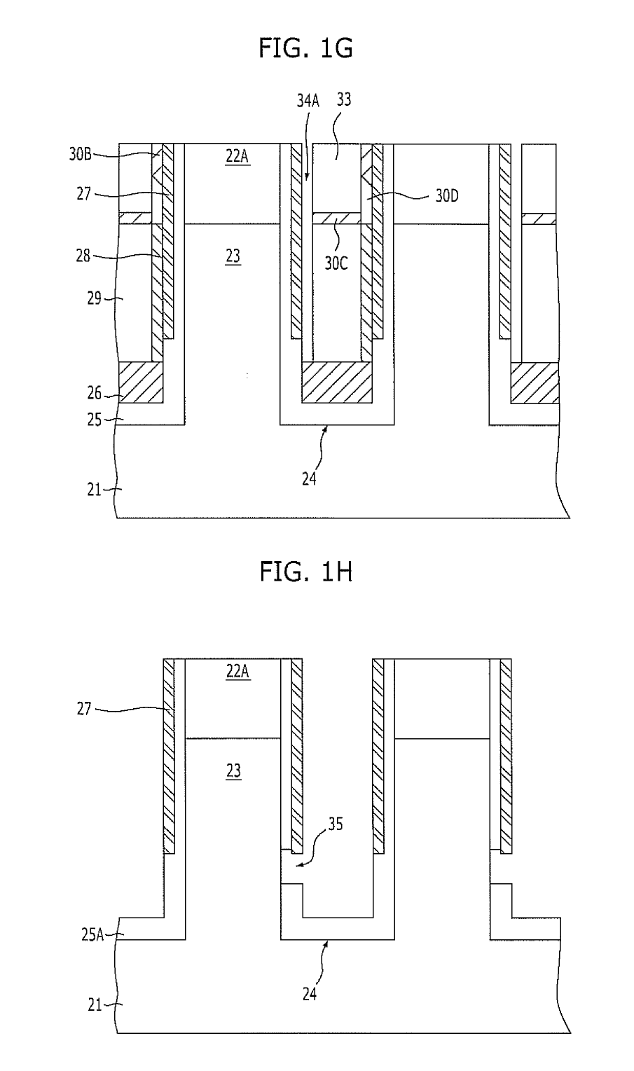

FIGS. 1A to 1H are cross-sectional views showing a method for fabricating a semiconductor device in accordance with an exemplary embodiment of the present invention.

Referring to FIG. 1A, a plurality of pillars 23 are formed on a substrate 21 while being separated from one another by trenches 24.

The pillar 23 is formed by etching the substrate 21 by a predetermined depth by using a hard mask pattern 22 as an etching barrier. The pillar 23 and the hard mask pattern 22 collectively are referred to as a “pillar structure”.

A gap-fill material is formed to partially fill the trench 24 between the pillars 23. The gap-fill material has a height suitable for exposing an upper sidewall of the pillar structure, and partially fills the trench 24. The gap-fill material includes a liner layer, a first sacrificial layer 26, a second sacrificial layer 28, and a third sacrificial layer 29. The liner layer is formed on the sidewall of the pillar 23 and the surface of the trench 24. The liner layer includes a first liner layer 25 and a second liner layer 27. The first liner layer 25 may include an oxide layer and the second liner layer 27 may include a nitride layer. The first sacrificial layer 26 has a height suitable for partially filling the lower portion of the trench 24 and exposing a part of the first liner layer 25. The second sacrificial layer 28 is provided in the form of a spacer that covers a lower portion of the sidewall of the second liner layer 27. The third sacrificial layer 29 is partially buried in the first sacrificial layer 26. The second sacrificial layer 28 and the third sacrificial layer 29 are in a recessed state, such that only their upper surfaces are exposed. Further, the upper portion of the sidewall of the second liner layer 27 is exposed and the exposed portion may have a height approximately the same as that of the hard mask pattern 22.

Referring to FIG. 1B, a masking layer 30 is formed on the resultant structure including the third sacrificial layer 29. The masking layer 30 includes a material which is etched at different speeds according to ion implantation. For example, the masking layer 30 may include undoped polysilicon.

The masking layer 30 is formed along the contour of the resultant structure including the gap-fill material partially filling the trench 24 between the pillars 23.

Referring to FIG. 1C, a first ion implantation 31 is performed.

In the first ion implantation 31, dopants are ion-implanted at a certain tilt angle. This process is referred to as tilt ion implantation. Through the tilt ion implantation, the dopant is implanted into a part of the masking layer 30.

The first ion implantation 31 is performed at a certain angle. This angle is referred to as a tilt angle. The tilt angle may be in the range of approximately 5° to approximately 30° with respect to the surface of the masking layer 30 on the upper surface of the hard mask pattern 22. Such a tilt angle is a relatively high tilt angle. In this regard, the first ion implantation 31 is also referred to as high tilt angle implantation (HTAI).

Since the first ion implantation 31 is performed at a high tilt angle, the hard mask pattern 22 blocks a part of an ion beam from doping the entire masking layer. In other words, the hard mask pattern 22 casts a shadow, which prevents part of the masking layer 30 from being doped. Thus, as a result of the first ion implantation 31, a part of the masking layer 30 is doped, but a remaining part of the masking layer 30 remains undoped. Herein, a part of the masking layer 30 that has been ion-implanted with the dopant is referred to as a first implanted portion 30B, and the remaining part of the masking layer 30 that has not ion-implanted with the dopant is referred to as a first non-implanted portion 30A. Further, the ion-implanted dopant may include, for example, a P type dopant, such as boron. In order to ion-implant boron, BF₂ is may be used as a dopant source.

Referring to FIG. 1D, a second ion implantation 32 is performed.

According to the second ion implantation 32, dopant is ion-implanted in the vertical direction or at a low tilt angle, so the ion beams are approximately perpendicular to the surface of the masking layer 30 on the upper surface of the hard mask pattern 22. Thus, unlike the first ion implantation 31, ion beams of the second ion implantation 32 are concentrated on the horizontal bottom surface of first non-implanted portion 30A. Since the second ion implantation is performed in the vertical direction or at the low tilt angle, it is referred to as low tilt angle implantation (LTAI).

As a result of the second ion implantation 32, the horizontal bottom surface of the first non-implanted portion 30A becomes implanted and is referred to as a second implanted portion 30G. Further, parts of the first non-implanted portion 30A, located on the sidewalls of the hard mask pattern 22, still remain undoped. Moreover, the remaining undoped parts on facing sidewalls of the hard mask pattern 22 have different heights. Herein, the shorter remaining undoped parts are referred to as short non-implanted portions 30D and the taller remaining undoped parts are referred to as tall non-implanted portions 30E.

In the second ion implantation 32, the dopant may include P type dopant, such as boron. In order to ion-implant boron, BF₂ may be used as dopant source.

As described above, the first ion implantation 31 and the second ion implantation 32 are performed, so that the masking layer 30 is partitioned to form the first implanted portion 30B, the second implanted portion 30C, the short non-implanted portion 30D, and the tall non-implanted portion 30E.

Referring to FIG. 1E, a fourth sacrificial layer 33 is formed to gap-fill the trench 24 (i.e., to fill the gap between the hard mask pattern 22). The fourth sacrificial layer 33 may include an oxide layer, such as a silicon oxide layer.

Subsequently, a planarization process is performed. The planarization process is performed such that the tall non-implanted portion 30E is exposed. The planarization process may be performed using an etch-back process or a chemical mechanical polishing (CMP) process. Since the short non-implanted portion 30D is formed with a shorter height as compared with the tall non-implanted portion 30E, the short non-implanted portion 30D is not exposed at the time of the planarization process. Further, as a result of the planarization process, the height of the hard mask pattern 22 may be reduced as indicated by reference numeral ‘22A’.

Referring to FIG. 1F, the tall non-implanted portion 30E, exposed by the planarization process, is selectively removed. Here, the masking layer 30 is etched at different speeds according to whether a dopant is doped therein. For example, undoped polysilicon has a fast wet etching speed in comparison to doped polysilicon. Thus, the undoped polysilicon may be selectively removed by performing a wet etch using a chemical with high selectivity thereby allowing doped polysilicon to remain. Although, the tall non-implanted portion 30EA may be removed using a wet etching process or a wet cleaning process, it may also be removed using a dry etching process.

After the tall non-implanted portion 30E is removed, only the first implanted portion 30B, the second implanted portion 30C, and the short non-implanted portion 30D remain. The second non-implanted portion 30D is not removed because it is protected by the fourth sacrificial layer 33.

Consequently, the tall non-implanted portion 30E adjacent to one sidewall of the hard mask pattern 22A is removed, so that a gap 34 is formed between the fourth sacrificial layer 33 and the hard mask pattern 22A. Moreover, no significant gap is formed at the facing sidewall of the hard mask pattern 22A (i.e., no significant gap is formed on the sidewall with the short non-implanted portion 30D).

As described above, in accordance with an exemplary embodiment of the present invention, the tilt ion implantation and the vertical ion implantation are sequentially performed and the tall non-implanted portion 30E is selectively removed after the fourth sacrificial layer 33 is formed and planarized, so that the masking layer 30 necessary for the OSC process is formed in a self-alignment manner. Consequently, a relatively wide process window of the masking layer may be ensured. In addition, since an expensive photomask process and photolithography process is not used, the product cost may be reduced.

In other exemplary embodiments, the vertical ion implantation is not performed so that the second implanted portion 30C is not formed. Instead, after the tilt ion implantation is performed, the sacrificial layer 33 is formed and planarized and a gap is created. However, in this case, the first non-implanted portion 30A (as shown in FIG. 1C) may be removed in whole to create the gap. That is, it may be difficult to remove only the tall non-implanted portion 30E to form the gap 34, as shown in FIG. 1F. Thus, in this case, where the vertical ion implantation is not used, the process window may not be as wide.

Referring to FIG. 1G, a part of the second sacrificial layer 28, which is under the gap 34, is removed. Thus, the depth of the gap 34 is extended and the deeper gap is indicated by reference numeral ‘34A’. More specifically, part of the second sacrificial layer 28 may be removed using a wet etching process. Further, a part of the second sacrificial layer 28, which is not exposed by the gap 34, remains adjacent to the sidewall of the pillar 23. The remaining part of the second sacrificial layer 28 is indicated by reference numeral ‘28A’. Consequently, a part of the first liner layer 25 is exposed at the bottom of the extended gap 34A.

Referring to FIG. 1H, the exposed part of the first liner layer 25 is removed to create an opening, referred to as a bit line contact 35, which exposes a part of the sidewall of a pillar 23. The remaining part of the first liner layer 25 is indicated by reference numeral ‘25A’. The bit line contact 35 may be formed while removing the fourth sacrificial layer 33 and the third sacrificial layer 29. Further, the fourth sacrificial layer 33 and the third sacrificial layer 29 may be removed using a cleaning process.

The cleaning process may include a wet cleaning process. The wet cleaning process may use hydrofluoric acid (HF), buffered oxide etchant (BOE) and/or the like. By using the wet cleaning process, a part of the first liner layer 25 may be removed to form the bit line contact 35. The bit line contact 35 is a line type opening extending along the sidewall of the pillar 23.

The first implanted portion 30B, the second implanted portion 30C, and the second non-implanted portion 30D are removed, and then the second sacrificial layer 28A is removed. The first sacrificial layer 26 may be simultaneously removed when the first implanted portion 30B, the second implanted portion 30C, and the second non-implanted portion 30D are removed.

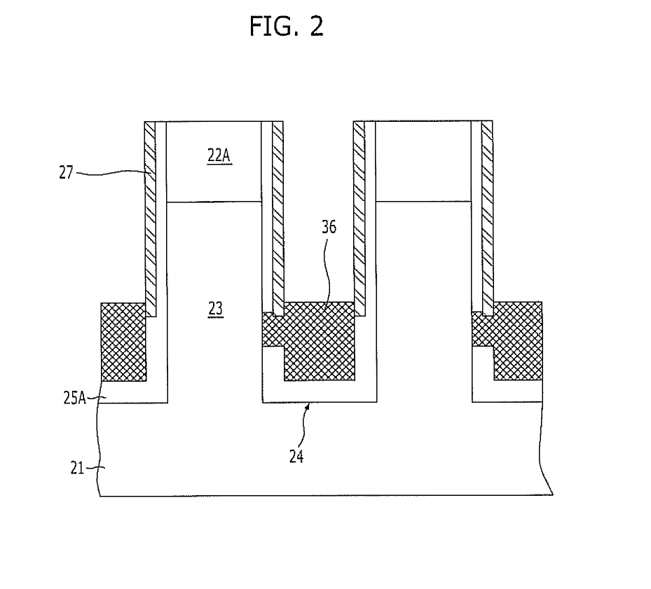

FIG. 2 is a diagram showing the resultant structure after a buried bit line is formed.

Referring to FIG. 2, a bit line conductive layer is formed on the resultant structure including the bit line contact (35 of FIG. 1H), and then an etch-back process is performed. Thus, a buried bit line 36 is formed, which is coupled to a part of one sidewall of the pillar 23 through the bit line contact. The bit line conductive layer may include a titanium nitride layer, a tungsten layer, and/or the like.

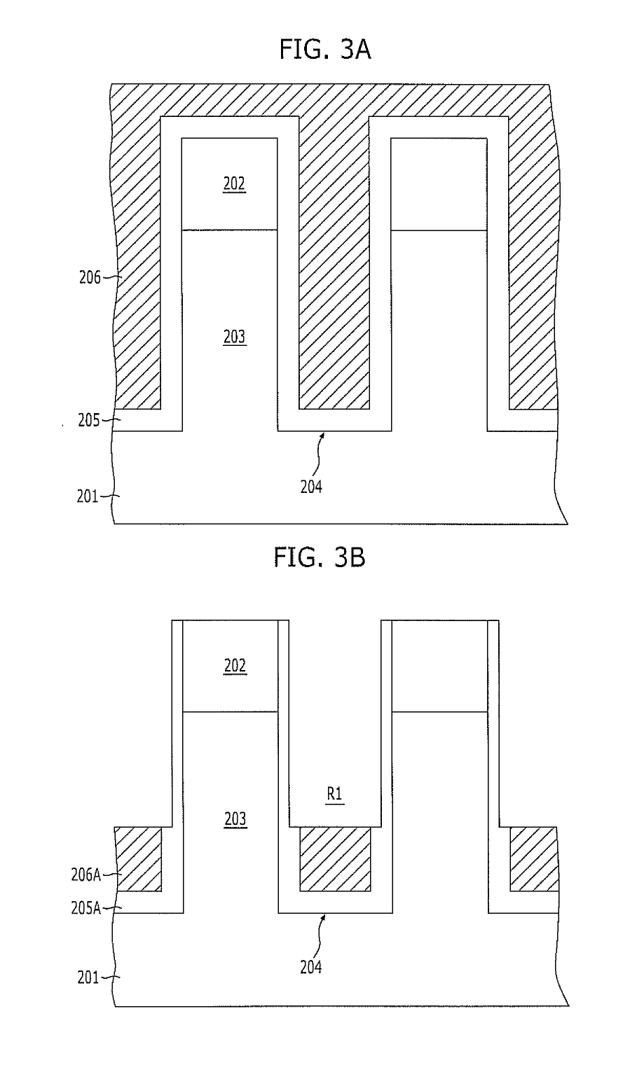

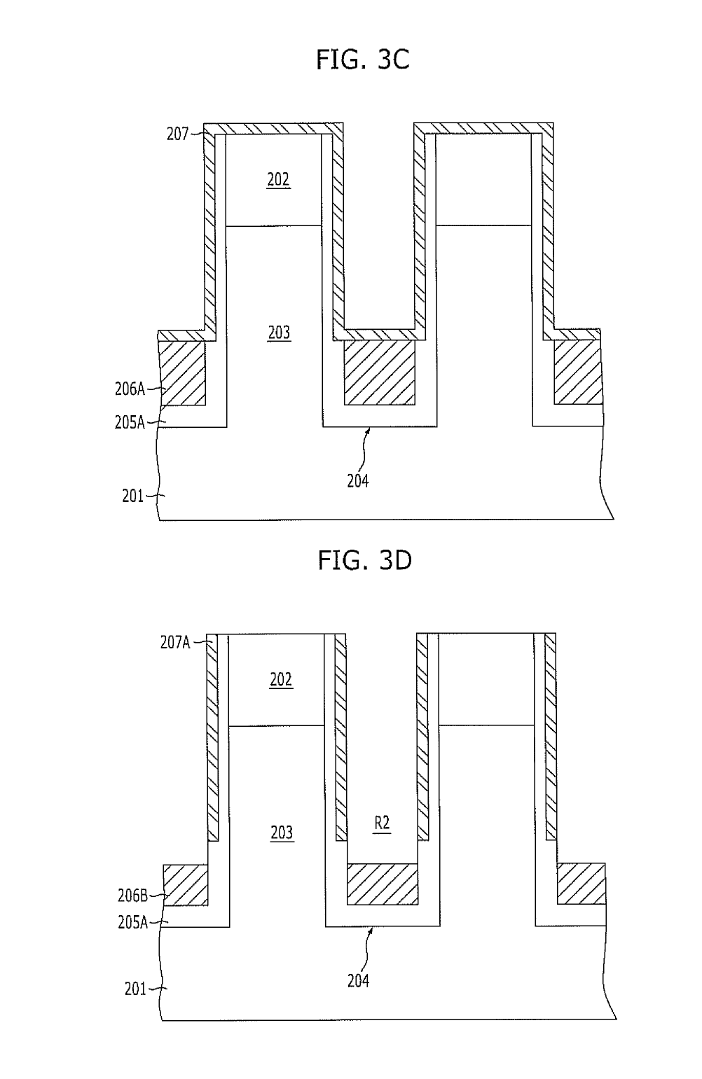

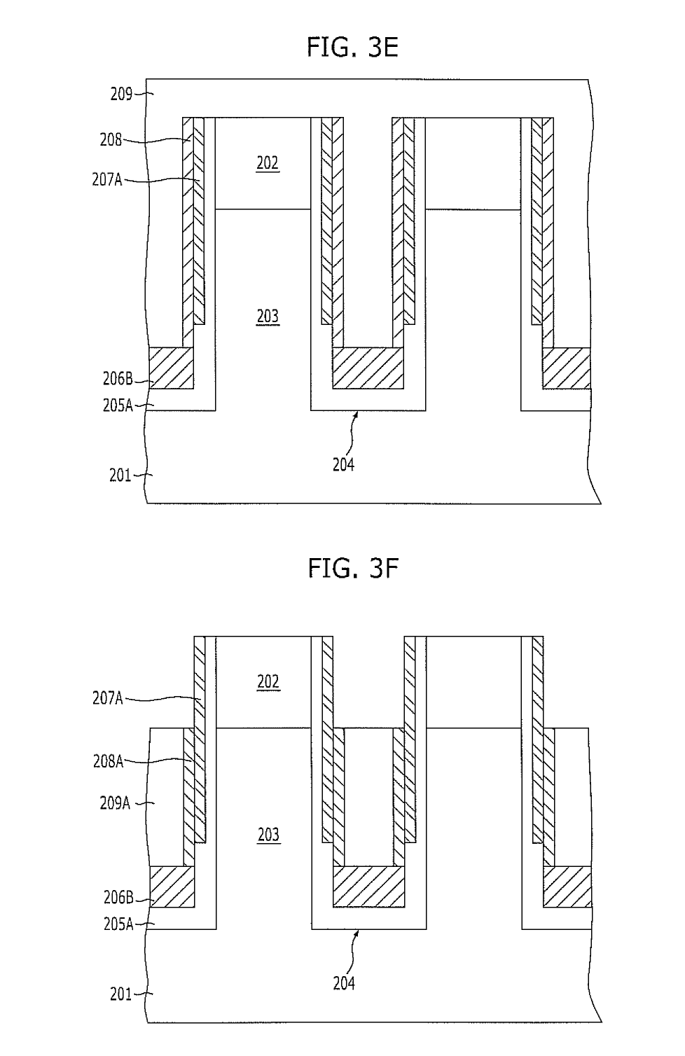

FIGS. 3A to 3F are cross-sectional views showing an example of how the pillar and the gap-fill material shown in FIG. 1A may be formed.

Referring to FIG. 3A, a hard mask pattern 202 is formed on a semiconductor substrate 201. The semiconductor substrate 201 may include a silicon substrate. The hard mask pattern 202 may include an oxide layer or a nitride layer, or may have a structure in which a nitride layer and an oxide layer are stacked. For example, a hard mask (HM) nitride layer and a hard mask (HM) oxide layer may be sequentially stacked. The hard mask pattern 202 is patterned with a line-space type pattern (i.e., parallel, line-shaped portions of the hard mask pattern 22 are separated by a space). The hard mask pattern 202 may be formed using a photoresist pattern (not shown).

A trench etching process is performed using the hard mask pattern 202 as an etching barrier. For example, the semiconductor substrate 201 is etched to a certain depth by using the hard mask pattern 202 as the etching barrier. Thus, a trench 204 is formed in the semiconductor substrate 201.

The trench etching process as described above is also referred to as a “BBL trench etching process”.

Since the trench 204 is formed by the hard mask pattern 202, the trench 204 is patterned with a line-space type pattern, as well. Thus, the trench 204 is a line type (i.e., the trench has a straight line shape).

The trench etching process may use anisotropic etching. When the semiconductor substrate 201 is a silicon substrate, the anisotropic etching may use a mixed gas of chlorine-based gas such as CCl₄ or Cl₂, bromide-based gas, such as HBr, and oxygen gas.

A pillar 203 is formed by the trench 204 as described above. The pillar 203 serves as an active region. The trench 204 is a trench in which a buried bit line is to be buried.

A first liner layer 205 is formed on the resultant structure, including the pillars 203. More specifically, the first liner layer 205 is formed along the contour of the resultant structure, including the pillar 203. The first liner layer 205 may include an oxide layer, such as a silicon oxide layer. Thus, the first liner layer 205 may be referred to as a liner oxide layer.

A first sacrificial layer 206 is formed on the first liner layer 205 to gap-fill the trench 204 between the pillars 203. The first sacrificial layer 206 may include undoped polysilicon or amorphous silicon.

Referring to FIG. 3B, the first sacrificial layer 206 is planarized until the surface of the hard mask pattern 202 is exposed. The planarization of the first sacrificial layer 206 may include a chemical mechanical polishing (CMP) process. Subsequently, an etch-back process is performed to partially remove the first sacrificial layer 206 in the trench 204. Thus, a first sacrificial pattern 206A is formed to partially fill the lower portion of the trench 204. At the time of the CMP process, the first liner layer 205 on the hard mask pattern 202 may be polished. Thus, a first liner pattern 205A remains, which covers both sidewalls of the hard mask pattern 202 and all surfaces of the trench 204.

The first liner pattern 205A is subject to a slimming process. The slimming process may be a wet etching process. A part of the first liner pattern 205A, which is adjacent to the first sacrificial pattern 206A, is not subject to the slimming process. Furthermore, the slimming process may be the same process as the etch-back process used to partially remove the first sacrificial layer 206 in the trench 204.

As described above, as a result of the etch-back process for forming the first sacrificial pattern 206A and the slimming process of the first liner pattern 205A, a first recess R1 is formed.

Referring to FIG. 3C, a second liner layer 207 is formed on the resultant structure, including the slimmed first liner pattern 205A. More specifically, the second liner layer 207 is formed along the contour of the resultant structure, including the pillars 203. The second liner layer 207 may include a nitride layer, such as a silicon nitride layer. Thus, the second liner layer 207 may also be referred to as a liner nitride layer.

Referring to FIG. 3D, a spacer etching process is performed. The spacer etching process uses an etch-back process. Thus, the second liner layer 207 is etch-backed. After the etch-back process is performed, the second liner layer remains in the form of a spacer on sidewalls of the hard mask pattern 202 and sidewalls of the pillars 203, as indicated by reference numeral ‘207A’. Through the above-described etch-back process, the second liner pattern 207A is formed.

The first sacrificial pattern 206A is recessed by a certain depth by using the second liner pattern 207A as an etching barrier. Thus, a second recess R2 is formed. The first sacrificial pattern including the second recess R2 is indicated by reference numeral ‘206B’. An etch-back process may be performed when forming the second recess R2.

Referring to FIG. 3E, a second sacrificial layer 208 adjacent to the sidewall of the second recess R2 is formed. The second sacrificial layer 208 serves as a wet barrier. The second sacrificial layer 208 may include a metal nitride layer, such as a titanium nitride layer (TiN). The second sacrificial layer 208 is formed by performing a spacer etching process. Thus, the second sacrificial layer 208 covers the sidewalls of the second liner pattern 207A.

A third sacrificial layer 209 is formed to gap-fill the second recess R2, including the second sacrificial layer 208. The third sacrificial layer 209 may include an oxide layer and/or a spin on dielectric (SOD) layer.

Referring to FIG. 3F, the third sacrificial layer 209 is planarized and then etch-backed. Thus, a recessed third sacrificial pattern 209A is formed. At the time of the formation of the third sacrificial pattern 209A or after the third sacrificial pattern 209A is formed, the second sacrificial layer 208 is etch-backed to form a second sacrificial pattern 208A having a reduced height, as shown in FIG. 3F. The third sacrificial pattern 209A and the second sacrificial pattern 208A may have the same surface height.

As described above, the third sacrificial pattern 209A is formed, thereby achieving the structure in which the gap-fill material is partially filled between the pillars 203. The gap-fill material includes the first liner pattern 205A, the second liner pattern 207A, the first sacrificial pattern 206B, the second sacrificial pattern 208A, and the third sacrificial pattern 209A.

In accordance with an exemplary embodiment of the present invention, both tilt ion implantation and vertical ion implantation are performed with respect to a masking layer, so that a wide process window may be ensured.

Consequently, it may be possible to easily form a bit line contact for opening one sidewall of a pillar at the time of the formation of a cell having a vertical transistor structure.

While the present invention has been described with respect to the specific embodiments, it will be apparent to those skilled in the art that various changes and modifications may be made without departing from the spirit and scope of the invention as defined in the following claims.

What is claimed is:

1. A method for forming a masking layer of a semiconductor device, comprising:
forming a plurality of pillar structures separated by a trench;
forming a gap-fill material partially filling the trench and exposing upper sidewalls of each pillar structure;
forming a masking layer that covers the pillar structures and the gap-fill material;
performing an ion implantation to the masking layer to form an implanted portion covering upper portion of the gap-fill material and one side of the upper sidewalls of each pillar structure and a non-implanted portion covering the other side of the upper sidewalls of each pillar structure;
forming a sacrificial layer over the masking layer;
exposing the non-implanted portion of the masking layer; and
selectively removing the exposed non-implanted portion.

2. The method of claim 1, wherein the exposing of the non-implanted portion of the masking layer comprises:
simultaneously planarizing the sacrificial layer and the masking layer such that the non-implanted portion is exposed.

3. The method of claim 2, wherein the simultaneous planarizing of the sacrificial layer and the masking layer is performed using a chemical mechanical polishing (CMP) process or an etch-back process.

4. The method of claim 1, wherein the masking layer comprises undoped polysilicon.

5. The method of claim 1, wherein the sacrificial layer comprises an oxide layer.

6. The method of claim 1, wherein the ion implantation includes:
a first ion implantation forming the implanted portion covering the one side of the upper sidewalls of each pillar structure; and
a second ion implantation forming the implanted portion covering the upper portion of the gap-fill material.

7. The method of claim 6, wherein the first ion implantation is a high tilt angle implantation and the second ion implantation is a vertical ion implantation or a low tilt angle implantation.

8. A method for fabricating a semiconductor device, comprising:
forming a plurality of pillar structures separated by a trench;
forming a gap-fill material partially filling the trench and exposing an upper sidewall of each pillar structure;
forming a masking layer that covers the pillar structures and the gap-fill material;
performing an ion implantation to the masking layer to form an implanted portion covering upper portion of the gap-fill material and one side of the upper sidewalls of each pillar structure and a non-implanted portion covering the other side of the upper sidewalls of each pillar structure;
exposing the non-implanted portion of the masking layer;
selectively removing the exposed non-implanted portion; and
forming a bit line contact for exposing a part of one sidewall of each pillar structure by partially removing a gap-fill material under the removed non-implanted portion.

9. The method of claim 8, wherein the exposing of the non-implanted portion of the masking layer comprises:
forming a sacrificial layer over the masking layer; and
simultaneously planarizing the sacrificial layer and the masking layer such that the non-implanted portion is exposed.

10. The method of claim 9, wherein the masking layer comprises undoped polysilicon.

11. The method of claim 9, wherein the sacrificial layer comprises an oxide layer.

12. The method of claim 9, wherein the simultaneous planarizing of the sacrificial layer and the masking layer is performed using a chemical mechanical polishing (CMP) process or an etch-back process.

13. The method of claim 8, wherein the exposing of one sidewall of each pillar structure is performed using a wet etching process or a dry etching process.

14. The method of claim 8, wherein the forming of the plurality of pillar structures separated by the trench comprises:
forming a hard mask pattern on a substrate; and
etching the substrate by a predetermined depth by using the hard mask pattern as an etching barrier.

15. The method of claim 8, wherein the gap-fill material comprises an oxide layer that covers a sidewall of each pillar structure and a surface of the trench.

16. The method of claim 8, wherein the gap-fill material comprises an oxide layer, a nitride layer, a titanium nitride layer, and undoped polysilicon, and the bit line contact is formed by partially removing the titanium nitride layer and the oxide layer.

17. The method of claim 8, wherein the ion implantation includes:
a first ion implantation forming the implanted portion covering the one side of the upper sidewalls of each pillar structure; and
a second ion implantation forming the implanted portion covering the upper portion of the gap-fill material.

18. The method of claim 17, wherein the first ion implantation is a high tilt angle implantation and the second ion implantation is a vertical ion implantation or a low tilt angle implantation.

19. A method for fabricating a mask of a semiconductor device, comprising:
forming a masking layer including a bottom surface and a sidewall;
forming a sacrificial layer covering the masking layer; and
performing an ion implantation to dope the bottom surface and an upper portion of the sidewall and undope a lower portion of the sidewall.

20. The method of claim 19, wherein the ion implantation includes:
a first ion implantation doping the bottom surface; and
a second ion implantation doping the upper portion of the sidewall, wherein the first ion implantation is a high tilt angle implantation and the second ion implantation is a vertical ion implantation or a low tilt angle implantation.
